(19) United States
(12) Patent Application Publication
(10) Pub. No.: US 2005/0104170 A1
(43) Pub. Date: May 19, 2005

(54) Semiconductor device and manufacturing method thereof

(76) Inventor: Akio Nakamura, Tokyo (JP)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 10/822,749

(22) Filed: Apr. 13, 2004

(30) Foreign Application Priority Data
Nov. 17, 2003 (JP) 386818/2003

(51) Int. Cl. H01L 23/495; H01L 21/48

(52) U.S. Cl. 257/676; 257/777; 257/787; 438/123

(57) ABSTRACT

The present invention provides a semiconductor device which comprises a die pad section (200) having a surface (201) and a back surface (202), a first semiconductor chip (4) having a surface (41) on which a first electrode section (47) is formed, and a back surface (42) fixed to the surface of the die pad section (200), a second semiconductor chip (5) having a surface (51) on which a second electrode section (57) is formed, and a back surface (52) fixed to the surface (41) of the first semiconductor chip (4), lead terminal sections (210 and 220) respectively electrically connected to the first and second electrode sections (47 and 57), and a resin encapsulating body (10) that seals the die pad section (200) and the first and second semiconductor chips (4 and 5). An edge portion (54) of the second semiconductor chip (5) protrudes from an edge portion (44) of the first semiconductor chip (4). An edge portion (204) of the die pad section (200) protrudes from an edge portion (44) of the first semiconductor chip (4).

### BACKGROUND OF THE INVENTION

1. Field of the Invention

The present invention relates to a semiconductor device and a method of manufacturing the same, and particularly to a semiconductor device of a semiconductor chip laminated type wherein a plurality of semiconductor chips are laminated, and a method of manufacturing the same.

2. Description of the Related Art

A patent document 1 has described a semiconductor device wherein semiconductor chips are laminated with being shifted from one another. In this type of semiconductor device, one of lead terminal sections of a lead frame is formed so as to extend. A first semiconductor chip is fixed onto an upper surface of such an extended portion. Further, a second semiconductor chip is laminated on the first semiconductor chip so that an edge portion of the second semiconductor chip protrudes from an edge portion of the first semiconductor chip. Furthermore, a third semiconductor chip is fixed to a lower surface of the extended portion, and a fourth semiconductor chip is laminated on the third semiconductor chip such that an edge portion of the fourth semiconductor chip protrudes from an edge portion of the third semiconductor chip.

Patent document 1

Japanese Unexamined Patent Publication No. 2001-298150 (see the fourteenth page and FIG. 9)

When an edge portion of a semiconductor chip does not protrude from an edge portion of another semiconductor chip, there is no need to take into consideration stress applied to a protruding portion. However, when the edge portion of the semiconductor chip protrudes from the edge portion of another semiconductor chip as in the structure described in the patent document 1, stress applied to such a protruding portion becomes a problem.

In the structure of the patent document 1, the edge portion of the fourth semiconductor chip protrudes from the third semiconductor chip, and no lead frame and other semiconductor chips exist above and below such a protruded edge portion. Therefore, when such a semiconductor device is detached from a die after having been sealed with a resin, stress to which the edge portion of the fourth semiconductor chip is subject due to resin deformation, is large. In particular, there is a fear that stress concentrates on a boundary portion (edge portion) at which the edge portion of the fourth semiconductor chip protrudes from the edge portion of the third semiconductor chip, and hence the fourth semiconductor chip breaks up at the edge portion.

### SUMMARY OF THE INVENTION

With the foregoing problems in view, it is therefore an object of the present invention to suppress deterioration of semiconductor chips due to stress in a semiconductor device of a semiconductor chip laminated type.

According to one aspect of the present invention, there is provided a semiconductor device sealed with a resin encapsulating body, comprising a die pad section having a surface and a back surface, first and second semiconductor chips, lead terminal sections, and the resin encapsulating body. The first semiconductor chip has a surface on which a first electrode section is formed, and a back surface fixed to the surface of the die pas section. The second semiconductor chip has a surface on which a second electrode section is formed, and a back surface fixed to the surface of the first semiconductor chip. The lead terminal sections are respectively electrically connected to the first and second electrode sections. The resin encapsulating body seals the die pad section and the first and second semiconductor chips. The semiconductor device is characterized in that an edge portion of the second semiconductor chip protrudes from an edge portion of the first semiconductor chip, and an edge portion of the die pad section protrudes from the edge portion of the first semiconductor chip.

In the semiconductor device according to the present invention, the die pad section protrudes from the first semiconductor chip on the same side as the portion (protruding portion) of the second semiconductor chip, which protrudes from the first semiconductor chip. Therefore, the resin encapsulating body is divided by the die pad section on the die pad section side of the protruding portion. Thus, when the semiconductor device subsequent to the resin encapsulation is dismounted from a die, it is possible to reduce stress to which the protruding portion is subject due to resin's deformation and suppress deterioration of the second semiconductor chip.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIG. 1 is a plan view of a semiconductor device 1 according to a first embodiment of the present invention;

FIG. 2 is a cross-sectional view of the semiconductor device 1 according to the first embodiment of the present invention;

FIG. 3 is an explanatory view of a method of manufacturing the semiconductor device 1;

FIG. 4 is an explanatory view of the method of manufacturing the semiconductor device 1;

FIG. 5 is an explanatory view of the method of manufacturing the semiconductor device 1;

FIG. 6 shows a simulation model;

FIG. 7 shows physical-property values of respective parts of the simulation model;

FIG. 8 illustrates a simulation result;

FIG. 9 shows level-by-level averages of maximum stresses over the entire semiconductor device;

FIG. 10 depicts level-by-level averages of maximum stresses at an edge portion;

FIG. 11 shows the relationship between a protruding portion of a die pad section and maximum stresses at the edge portion;

FIG. 12 is a cross-sectional view of a semiconductor device 1 according to a second embodiment of the present invention;

FIG. 13 shows a comparison between stresses based on the presence or absence of a through portion;

FIG. 14 illustrates examples of shapes of through portions;

FIG. 15 is a cross-sectional view of a semiconductor device 1 according to a third embodiment of the present invention; and

FIG. 16 is a cross-sectional view of the semiconductor device 1 according to the third embodiment of the present invention;

FIG. 17 is a plan view of a semiconductor device 1 according to a fourth embodiment of the present invention;

FIG. 18 is a plan view of the semiconductor device 1 according to the fourth embodiment of the present invention;

FIG. 19 is a plan view of a semiconductor device 1 according to a fifth embodiment of the present invention; and

FIG. 20 is a plan view of a semiconductor device 1 according to a sixth embodiment of the present invention.

### DETAILED DESCRIPTION OF THE INVENTION

Preferred embodiments of the present invention will be described hereinbelow in detail with reference to the accompanying drawings.

### First Embodiment

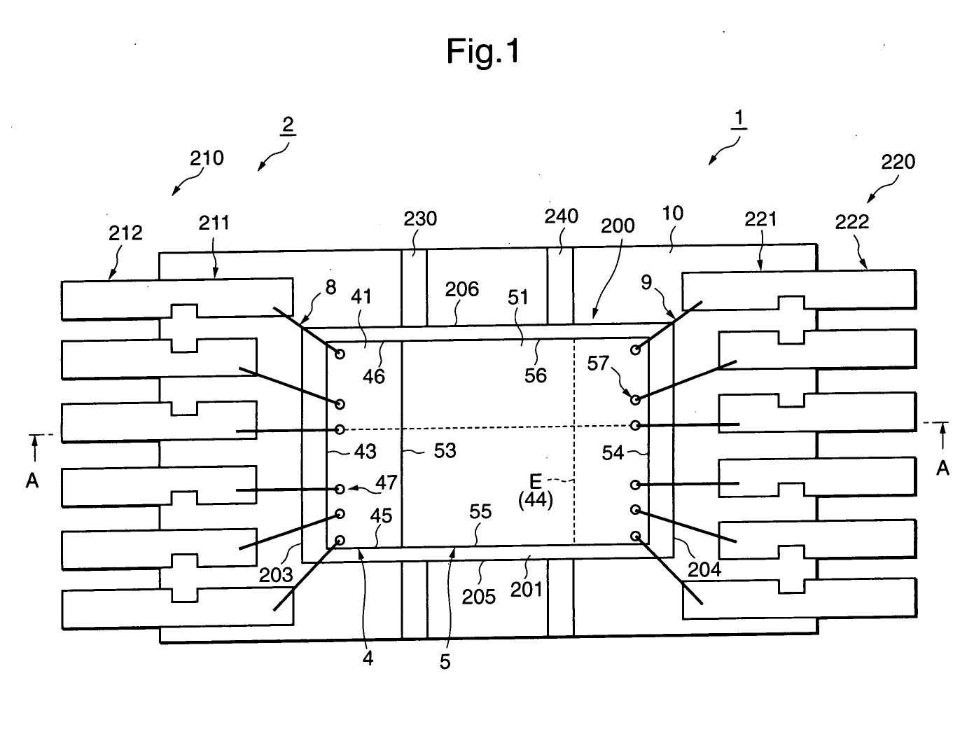

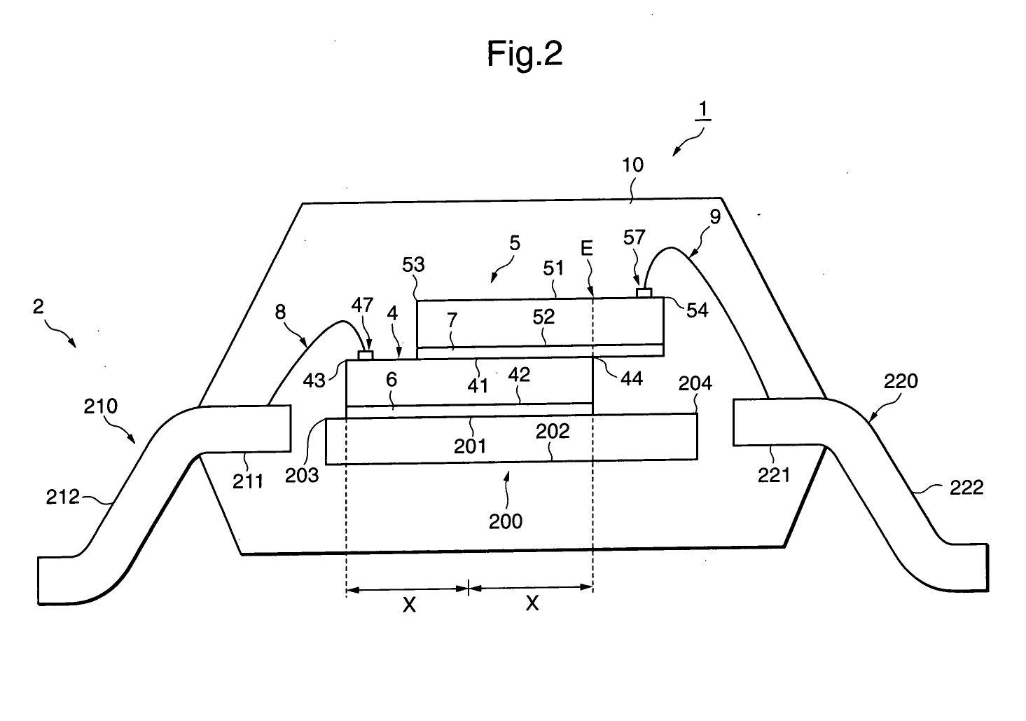

FIG. 1 is a top perspective diagram (corresponding to a diagram from which an upper portion of an upper resin encapsulating body is omitted) of a semiconductor device 1 according to a first embodiment of the present invention, and FIG. 2 is a cross-sectional view taken along line A-A of FIG. 1, respectively. The semiconductor device 1 is a semiconductor memory device, for example.

The semiconductor device 1 comprises a lead frame 2 having a die pad section 200 and lead terminal sections 210 and 220, and semiconductor chips 4 and 5.

The lead frame 2 includes the die pad section 200, the lead terminal sections 210 and 220 disposed on both sides of the die pad section 200 with a predetermined interval (0.3 mm or more) defined therebetween, and support portions 230 and 240 for supporting the die pad section 200. The die pad section 200 is shaped in the form of a substantially rectangle as seen in the flat surface and has surfaces 201 and 202 opposite to each other. The surface 201 includes sides 203 and 204 opposite to each other, and sides 205 and 206 respectively adjacent to the sides 203 and 204 and opposite to each other. The die pad section 200 is fixed to the support portions 230 and 240 respectively disposed along the sides 203 and.204. The lead terminal section 210 comprises a plurality of lead terminals. The plurality of lead terminals of the lead terminal section 210 are disposed along the side 203 with a predetermined interval (0.3 mm or more) with respect to the side 203 on the side 203 side of the die pad section 200. The lead terminal section 210 has inner portions 211 disposed inside the resin encapsulating body 10, and outer portions 212 disposed outside the resin encapsulating body 10. The outer portions 212 are respectively bent in matching with the layout of external terminals. The lead terminal section 220 consists of a plurality of lead terminals. The plurality of lead terminals of the lead terminal section 220 are disposed along the side 204 with a predetermined interval (0.3 mm or more) with respect to the side 204 on the side 204 side of the die pad section 200. The lead terminal section 220 includes inner portions 221 disposed inside the resin encapsulating body 10, and outer portions 222 disposed outside the resin encapsulating body 10. The outer portions 222 are respectively bent in matching with the layout of external terminals. The lead terminal section 210 and the lead terminal section 220 are disposed so as to be opposed to each other with the die pad section 200 interposed therebetween.

The semiconductor chip 4 is substantially rectangular as seen in the plane surface and has surfaces 41 and 42 opposite to each other. The surface 41 has sides 43 and 44 opposite to each other, and sides 45 and 46 adjacent to the sides 43 and 44 and opposite to each other. In the present embodiment, the length (2X) between the sides 43 and 44 of the semiconductor chip 4, i.e., the length of each of the sides 45 and 46 is set to 11.4 mm. The semiconductor chip 4 has an electrode section 47 on the side 43 side of the surface 41. The electrode section 47 comprises a plurality of electrodes. The plurality of electrodes of the electrode section 47 are disposed along the side 43. The thickness of the semiconductor chip 4 is set to, for example, 0.02 to 0.06 times one-half X=5.7 mm of the length between the sides 43 and 44 of the semiconductor chip 4. The semiconductor chip 4 is fixed to the surface 201 of the die pad section 200 over the entire surface of the surface 42 by an adhesive 6 such that the side 43 is disposed on the side 203 side of the die pad section 200. The length between the side 43 of the semiconductor chip 4 and the side 203 of the die pad section 200 is set to 0.1 mm or more.

The semiconductor chip 5 has surfaces 51 and 52 opposite to each other. The surface 51 has sides 53 and 54 opposite to each other, and sides 55 and 56 respectively adjacent to the sides 53 and 54 and opposite to each other. Here, the semiconductor chip 5 has the same shape and size as the semiconductor chip 4. The length between the sides 53 and 54, i.e., the length of each of the sides 55 and 56 is 2X=11.4 mm. The semiconductor chip 5 has an electrode section 57 on the side 54 side of the surface 51. The electrode section 57 comprises a plurality of electrodes. The plurality of electrodes of the electrode section 57 are disposed along the side 54. The thickness of the semiconductor chip 5 is set to, for example, 0.02 to 0.06 times one-half X=5.7 mm of the length between the sides 53 and 54 of the semiconductor chip 5.

The semiconductor chip 5 is fixed to the semiconductor chip 4 by an adhesive 7 in a state in which the surface 52 thereof is being directed to the surface 41 of the semiconductor chip 4. Described in more detail, the semiconductor chip 5 is fixed to the semiconductor chip 4 in such a manner that the side 53 of the semiconductor chip 5 is Located inside from the side 43 of the semiconductor chip 4, and the side 54 of the semiconductor chip 5 is placed outside from the side 44 of the semiconductor chip 4 and inside from the side 204 of the die pad section 200. That is, as shown in FIG. 1, the semiconductor chips 4 and 5 are disposed so as to be contained in the die pad section 200 as viewed in the plane surface. In the following description, a boundary portion of the semiconductor chip 5, which protrudes outwardly of the semiconductor chip 4, is defined as an edge portion E. The edge portion E corresponds to a portion of the semiconductor chip 5 as viewed above the side 44 of the semiconductor chip 4.

A wiring section 8 electrically connects the electrode section 47 to the lead terminal section 210 lying on the near side as viewed from the electrode section 47. The wiring section 8 comprises a plurality of metal wires. The metal wires of the wiring section 8 connect the electrodes of the electrode section 47 and the lead terminals of the lead terminal section 210 by wire bonding, for example. A wiring section 9 electrically connects the electrode section 57 to the lead terminal section 220 lying on the near side as viewed from the electrode section 57. The wiring section 9 comprises a plurality of metal wires. The metal wires of the wiring section 9 connect the electrodes of the electrode section 57 and the lead terminals of the lead terminal section 220 by wire bonding, for example.

The resin encapsulating body 10 seals the lead frame 2, the semiconductor chips 4 and 5 and the wiring sections 8 and 9 for the purpose of protecting the respective parts. Described in more detail, the inner portions 211 and 221 of the lead terminal sections 210 and 220 are sealed with the resin encapsulating body 10, whereas the outer portions 212 and 222 of the lead terminal sections 210 and 220 are exposed outside of the resin encapsulating body 10.

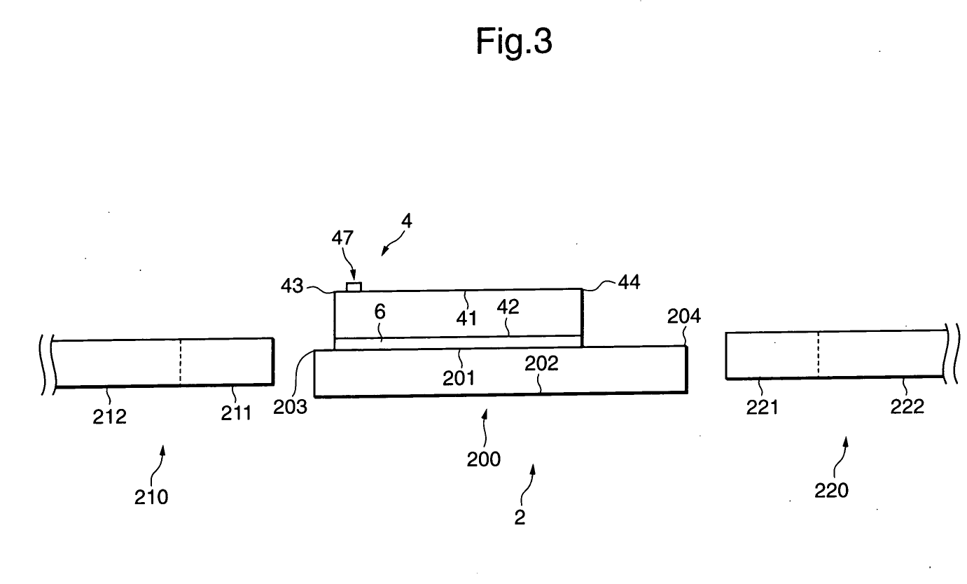

FIGS. 3 through 5 are respectively cross-sectional views for describing a method of manufacturing the semiconductor device 1 according to the present embodiment.

Firstly, as shown in FIG. 3, a semiconductor chip 4 is adhered to a surface 201 of a die pad section 200 by an adhesive 6 over the entire area of a surface 42 thereof in such a manner that the surface 42 thereof is directed to the surface 201 of the die pad section 200 and a side 43 thereof is located on the side 203 side. At this time, the semiconductor chip 4 is fixed to the die pad section 200 such that the side 43 of the semiconductor chip 4 is located inside by 0.1 mm or more from the side 203 of the die pad section 200.

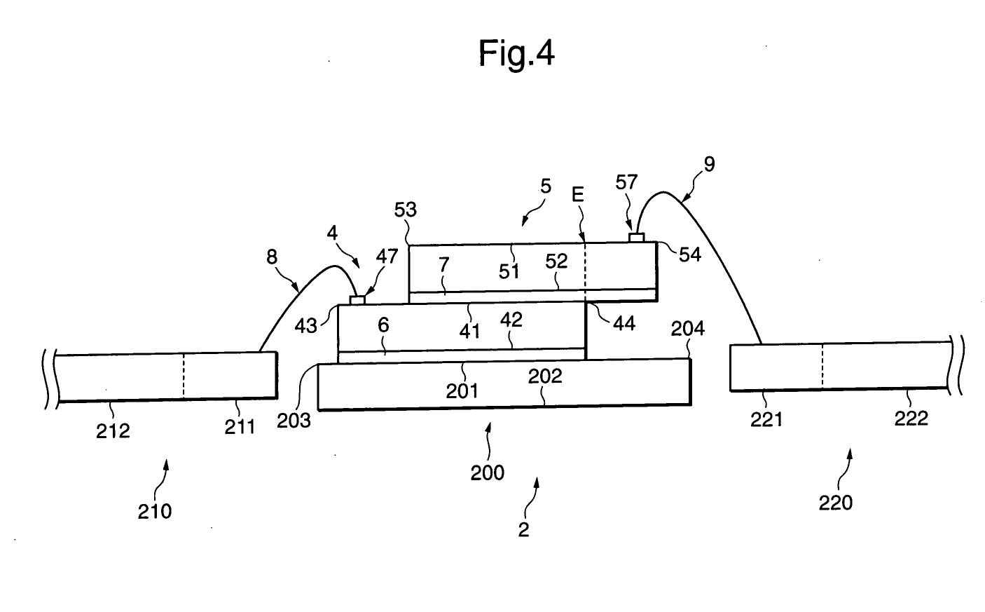

Next, as shown in FIG. 4, a semiconductor chip 5 is fixed to the semiconductor chip 4 by an adhesive 7 in such a manner that in a state in which a surface 52 of the semiconductor chip 5 is placed face to face with a surface 41 of the semiconductor chip 4, a side 53 of the semiconductor chip 5 is located inside from the side 43 of the semiconductor chip 4 and a side 54 thereof is located outside from a side 44 of the semiconductor chip 4 and inside from a side 204 of the die pad section 200. At this time, the length of a portion (protruding portion) of the side 54 of the semiconductor chip 5, which protrudes outside from the side 44 of the semiconductor chip 4, corresponds to the length of the side 53 of the semiconductor chip 5, which is shifted inwardly of the side 43 of the semiconductor chip 4. The length (length between an edge portion E and the side 54) of the protruding portion may be such a length that an electrode section 47 of the semiconductor chip 4 is exposed and the electrode section 47 and a lead terminal section 210 become wirable.

After the semiconductor chips 4 and 5 have been fixed, a plurality of electrodes constituting the electrode section 47 of the semiconductor chip 4 are respectively connected to a plurality of lead terminals of a lead terminal section 210 located on the near side as viewed from the electrode section 47 through a plurality of metal wires of a wiring section 8 by wire bonding. Also a plurality of electrodes constituting an electrode section 57 of the semiconductor chip 5 are respectively connected to a plurality of lead terminals of a lead terminal section 220 located on the near side as viewed from the electrode section 57 through a plurality of metal wires of a wiring section 9 by wire bonding.

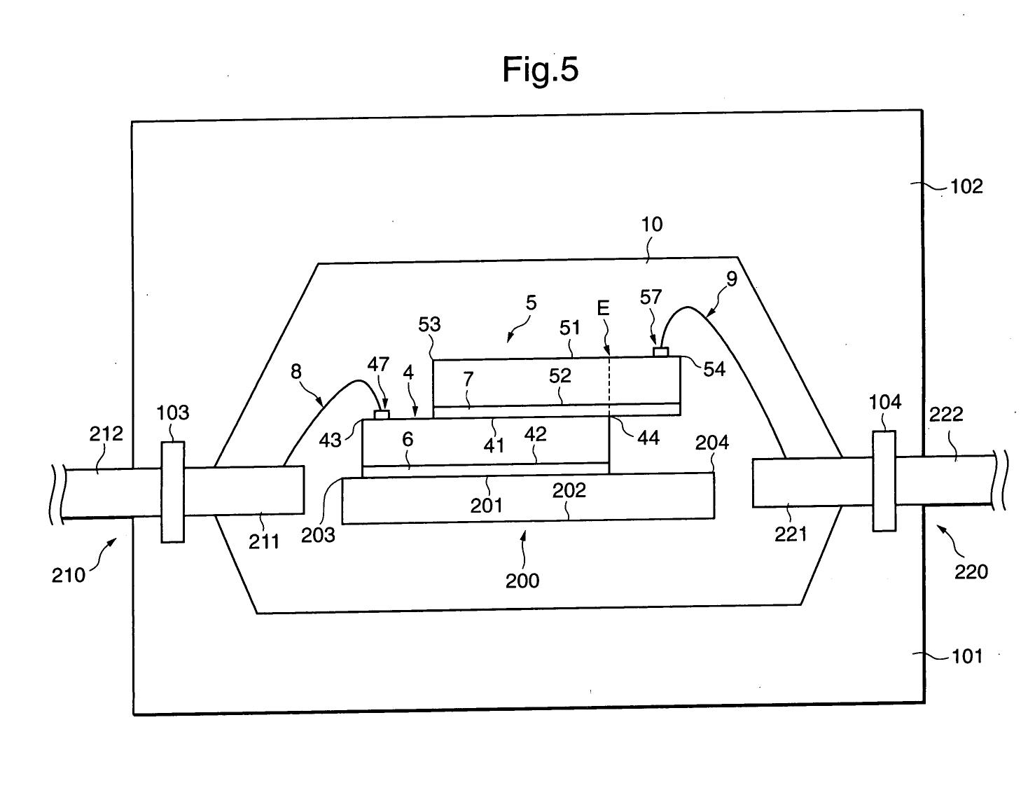

Next, as shown in FIG. 5, the lead terminal sections 210 and 220 of a lead frame 2 are respectively fixed to dies 101 and 102 by pins 103 and 104, and a resin is encapsulated therein by a transfer molding method to form or mold a resin encapsulating body 10. The lead frame 2 is fixed to the dies 101 and 102 in such a manner that inner portions 211 and 221 of the lead terminal sections 210 and 220 are accommodated inside the dies 101 and 102 and outer portions 212 and 222 of the lead terminal sections 210 and 220 are disposed outside the dies 101 and 102. The lead frame 2 fixed with the resin encapsulating body 10 is detached from the dies 101 and 102. Thereafter, the extra portions of the outer portions 212 and 222 of the lead terminal sections 210 and 220 are cut. Then, the outer portions 212 and 222 of the lead terminal sections 210 and 220 are bent in matching with the layout of external terminals, thus leading to their completion.

A description will next be made of the result of simulation of both the maximum stresses over the entire semiconductor device 1 and the maximum stresses at the edge portion E by changing dimensional values of the respective parts of the semiconductor device 1.

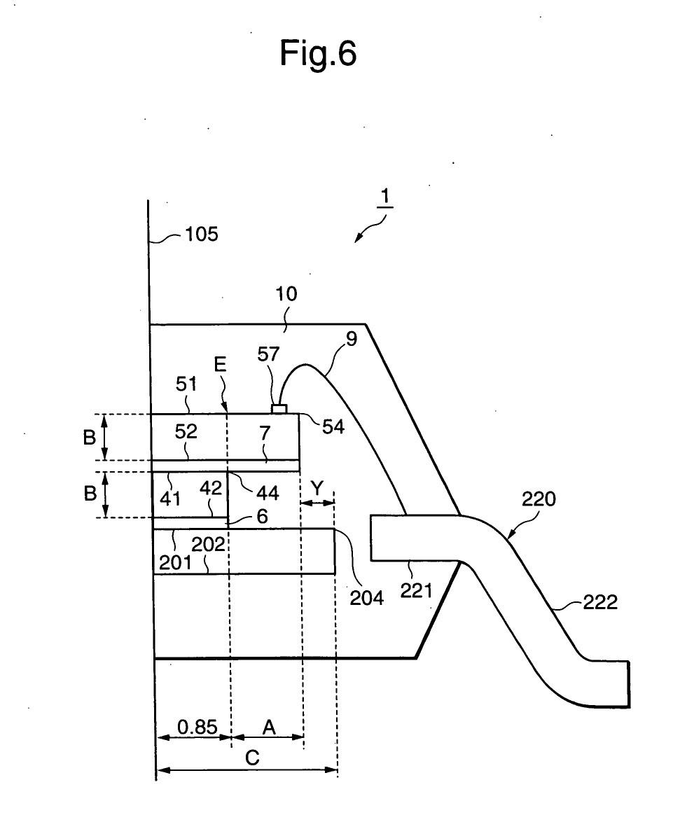

FIG. 6 is a simulation model of the semiconductor device 1 used in simulation. In the simulation model, the maximum stresses that act on the respective parts are simulated at the half portion of the die pad section 200 on the side 204 side where the die pad section 200 of the semiconductor device 1 is divided into two by a fixed line 105. This simulation is done in the following manner. That is, the maximum stresses applied onto the entire semiconductor device 1 and the maximum stresses at the edge portion E are calculated where in the simulation model shown in FIG. 6, the amount of displacement (length between the edge portion E and the side 54) A of the semiconductor chip 5 relative to the semiconductor chip 4, the thickness B of each of the semiconductor chips 4 and 5, and a half C of the length between the sides 203 and 204 of the die pad section 200 are varied and a load of 0.1 kg is applied to the outer peripheral portion of the resin encapsulating body 10. The stress applied onto the entire semiconductor device 1 is defined as the stress at the fixed line 105. The amount of displacement A of the semiconductor chip 5 relative to the semiconductor chip 4, the thickness B of each of the semiconductor chips 4 and 5, and the half C of the length between the sides 203 and 204 of the die pad section 200 are called simply the amount of displacement A, chip thickness B and a half C of a die pad length respectively. Further, the length of the side 204 of the die pad section 200, which protrudes outside from the side 54 of the semiconductor chip 5, is defined as Y.

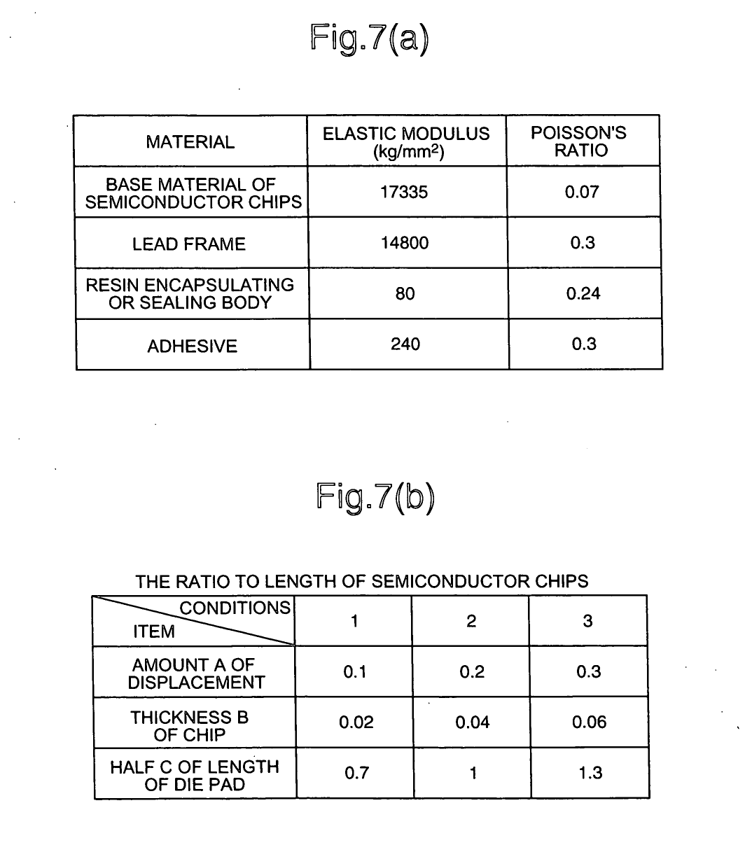

FIG. 7 shows physical-property values of the respective parts of the simulation model. FIG. 7(a) illustrates elastic moduli and Poisson's ratios of a base material for the semiconductor chips 4 and 5, the lead frame 2, the resin encapsulating body 10 and the adhesives 6 and 7. As shown in FIG. 7(a), the resin encapsulating body 10 is small in elastic modulus and large in Poisson's ratio as compared with the base material for the semiconductor chips 4 and 5 and the lead frame 2. The difference between the elastic modulus and the Poisson's ratio referred to above leads to the occurrence of large stress in the lead frame 2 and the semiconductor chips 4 and 5. FIG. 7(b) shows conditions (dimensions) used in simulation for every amount of displacement A, chip thickness B and the half C of die pad length. Here, the respective dimensions are represented in the form of ratios set with a half X=5.7 mm of the distance between the sides 53 and 54 of the semiconductor chip 5 as the reference. For instance, when the condition 1=0.1, the amount of displacement A is represented as 0.1×5.7=0.57 mm. When the condition 1=0.02, the chip thickness B is represented as 0.02×5.7=0.114 mm. When the condition 1=0.7, the half C of die pad length is represented as 0.7×5.7=3.99 mm.

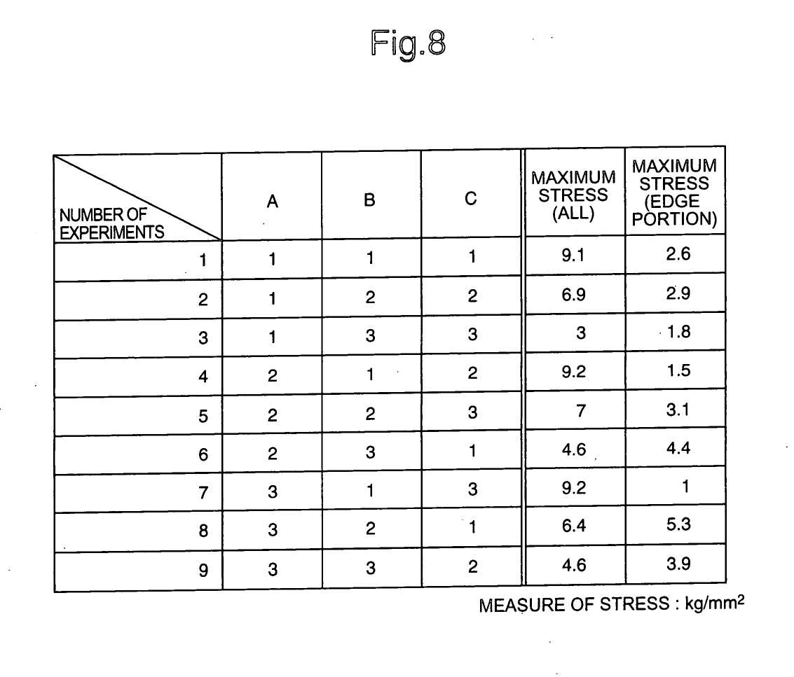

FIG. 8 shows results of experiments Nos. 1 to 9 where the amount of displacement A, chip thickness B and the half C of die pad length are changed to calculate stress. In the case of the experiment No. 1, for example, the amount of displacement A is represented as the condition 1=0.1, the chip thickness B is represented as the condition 1=0.01, and the half C of die pad length is represented as the condition 1=0.7.

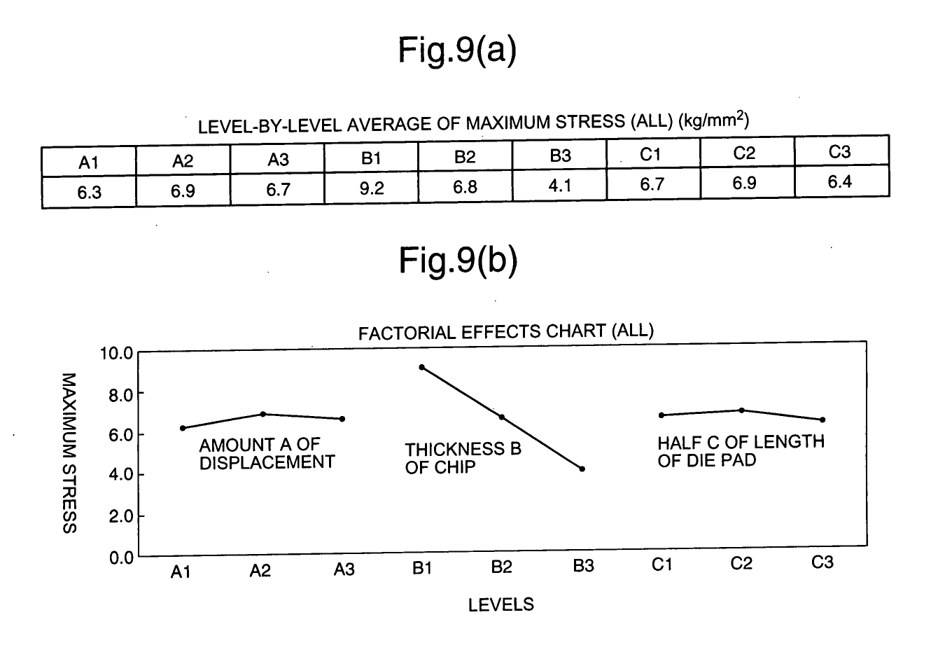

FIG. 9(a) shows level-by-level averages obtained by averaging results of calculation of the maximum stresses applied onto the entire semiconductor device 1 shown in FIG. 8 every levels A1 to C3, and FIG. 9(b) shows the level-by-level averages in the form of graphs. In the same drawing, for example, the level C1 indicates the average of the maximum stresses over the entire semiconductor device 1 where the half C of die pad length is of the condition 1 in FIG. 8. Also the level C1 is equivalent to the average (9.1+4.6+6.4)/3=6.7 kg/mm² of the results of calculation of the maximum stresses over the entire semiconductor device 1 at the experiments Nos. 1, 6 and 8 where the half C of die pad length is of the condition 1.

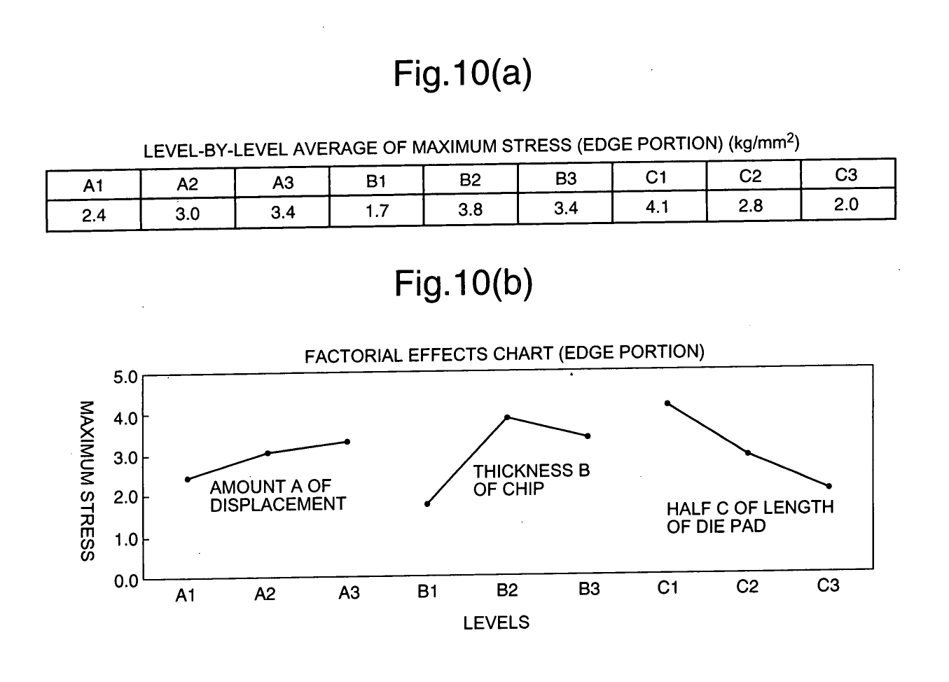

FIG. 10(a) illustrates level-by-level averages obtained by averaging results of calculation of the maximum stresses at the edge portion E in FIG. 8 every levels Al to C3, and FIG. 10(b) shows the level-by-level averages in the form of graphs. For example, the level C1 indicates the average of the maximum stresses at the edge portion E where the half C of die pad length is of the condition 1 in FIG. 8. Also the level C1 is calculated from the average (2.6+4.4+5.3)/3=4.1 kg/mm² of the results of calculation of the maximum stresses (at the edge portion) at the experiments Nos. 2, 6 and 8 where the half C of die pad length is of the condition 1.

It is understood that at the mention of the amount of displacement A by referring to FIGS. 9 and 10, the stress applied onto the entire semiconductor device 1 does not show a noticeable change according to the amount of displacement A, whereas the stress at the edge portion E becomes gradually large with an increase in the amount of displacement A. As to the chip thickness B, the stress applied onto the entire semiconductor device 1 decreases with an increase in the chip thickness B, whereas the stress at the edge portion E increases from the chip thickness B1 to the chip thickness B2 and decreases from the chip thickness B2 to the chip thickness B3. It is understood that as to the half C of die pad length, the stress applied onto the entire semiconductor device 1 does not show a noticeable change according to the half C of die pad length, whereas the stress at the edge portion E substantially decreases with an increase in the half C of die pad length. It is thus expected from the level-by-level averages shown in FIGS. 9 and 10 that as the die pad section 200 becomes long, i.e., the side 204 of the die pad portion 200 protrudes outside from the side 54 of the semiconductor chip 5, the maximum stress at the edge portion E will be reduced.

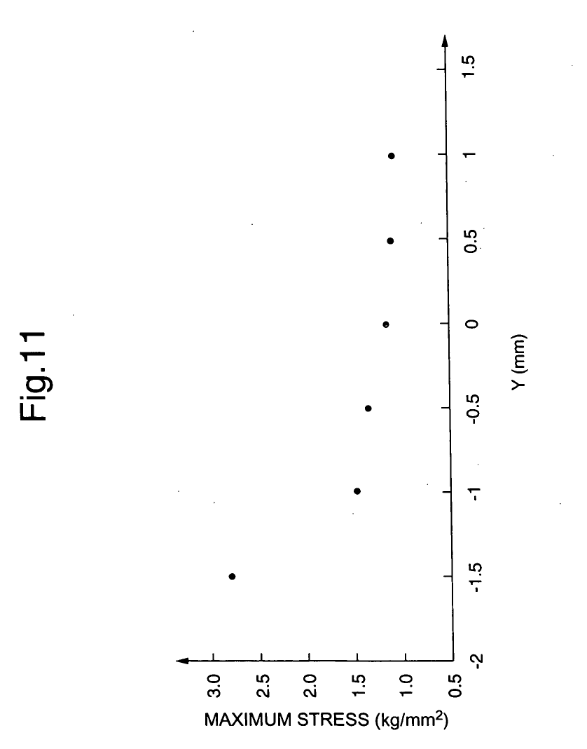

FIG. 11 is a graph showing a result of simulation of maximum stresses at the edge portion E where Y (the length of the side 204 of the die pad section 200, which protrudes outside from the side 54 of the semiconductor chip 5) shown in FIG. 6 is changed. Here, only the half C of die pad section was changed with the amount of displacement A as the condition 3=0.3 and the chip thickness B as the condition 1=0.02. Here, X<0 shows where the side 204 of the die pad section 200 is located inside from the side 54 of the semiconductor chip 5.

It is understood from the same drawing that as the length Y of the side 204 of the die pad section 200, which protrudes outside from the side 54 of the semiconductor chip 5 increases (as the length of the side 204 of the die pad section 200, which protrudes from the side 44 of the semiconductor chip 4, becomes long), the maximum stress at the edge portion E decreases. It is considered that this is because as the length of the side 204 of the die pad section 200, which protrudes from the side 44 of the semiconductor chip 4, increases, the influence of deformation of the resin on the side 202 side of the die pad section 200 on deformation of the resin on the surface 201 side is reduced so that the stress of the deformation of the resin on the surface 201 side on the protruding portion of the semiconductor chip 5 is lessened and the stress at the edge portion E of the semiconductor chip 5 is also reduced.

According to the semiconductor device 1 according to the present embodiment, since the die pad section 200 is disposed so as to overlap with the portion of the semiconductor chip 4 that protrudes from the semiconductor chip 5, the maximum stress that acts on the edge portion E of the semiconductor chip 5 is reduced so that deterioration of the semiconductor chip 5 at the edge portion E can be suppressed upon the process of assembling the semiconductor chip 5 (upon taking out the semiconductor device 1 subsequent to the resin encapsulation from the die). The more the length of the side 204 of the die pad section 200, which protrudes outside from the side 44 of the semiconductor chip 4, increases, the more the effect of suppressing deterioration of the semiconductor chip 5 at the edge portion E increases.

Incidentally, although the adhesive 7 is placed on the entire area of the surface 52 of the semiconductor chip 5 as described above, the adhesive 7 is placed on only the portion that overlaps with the semiconductor chip 4, i.e., the portion between the side 53 of the surface 52 and the edge portion E, and the semiconductor chip 5 may be fixed to the semiconductor chip 4.

### Second Embodiment

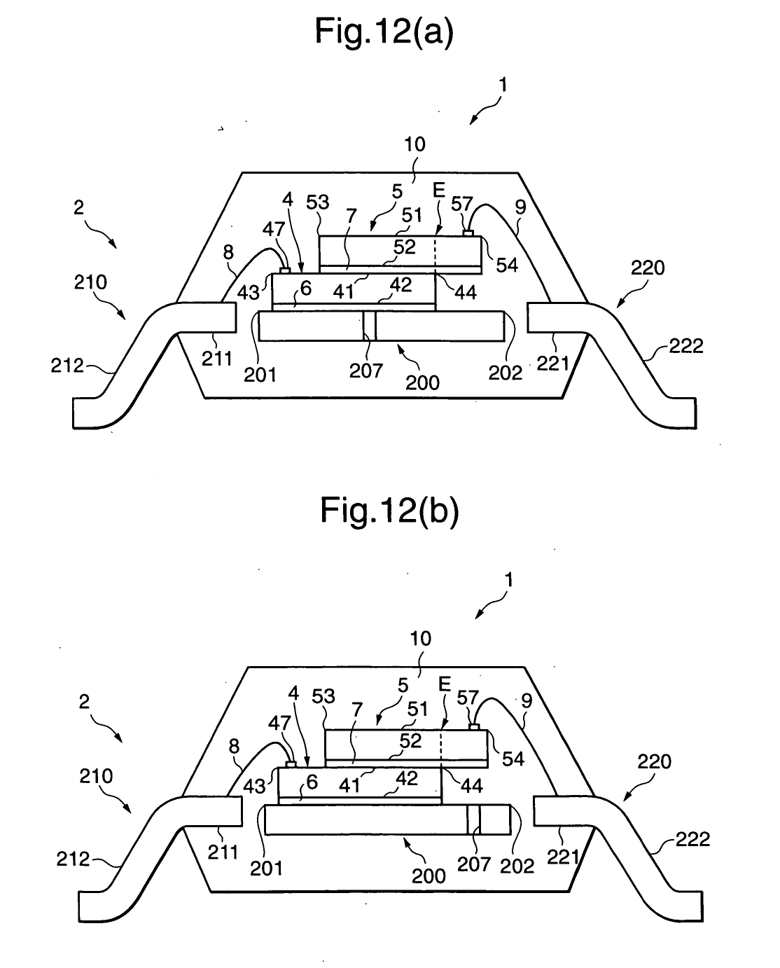

FIG. 12(a) is a cross-sectional view of a semiconductor device 1 according to a second embodiment of the present invention. The semiconductor device 1 according to the present embodiment is different from the first embodiment in that in a die pad section 200, a through section 207 is defined in a portion where semiconductor chips 4 and 5 overlap each other. The formation of the through section 207 at the portion where the semiconductor chips 4 and 5 overlap each other is that most of the through section 207 is formed at the portion where the semiconductor chips 4 and 5 overlap each other. Part of the through section 207 may be defined in a portion (portion where only the semiconductor chip 4 is fixed) other than the portion where the semiconductor chips 4 and 5 overlap each other.

In the above-described semiconductor device 1 of semiconductor chip laminated type, the through section has heretofore been defined in the die pad section 200 with a view toward relaxing stress produced between the die pad section 200 and the semiconductor chip 4 due to thermal expansion produced upon packaging the semiconductor device 1 on a mother board or the like. A portion of the through section defined in the die pad section 200 is a brittle portion weak in strength as compared with other portions, which in turn causes the stress produced due to thermal expansion to concentrate on the portion of the brittle through section to thereby prevent warpage of the entire die pad section 200. However, there is a fear that since the through section has heretofore been defined in the portion where only the semiconductor chip 4 is fixed in the die pad section 200, the strength of the semiconductor chip 4 is weak at an upper portion of the through section, and the semiconductor chip 4 is deteriorated at the upper portion of the through section when stress is concentrated on the portion of the through section upon the process of assembling the semiconductor device 1 (particularly upon disassembling the semiconductor device 1 subsequent to resin encapsulation from the corresponding die).

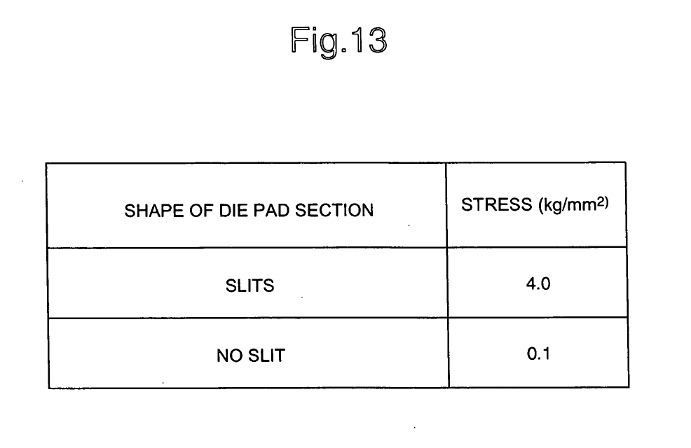

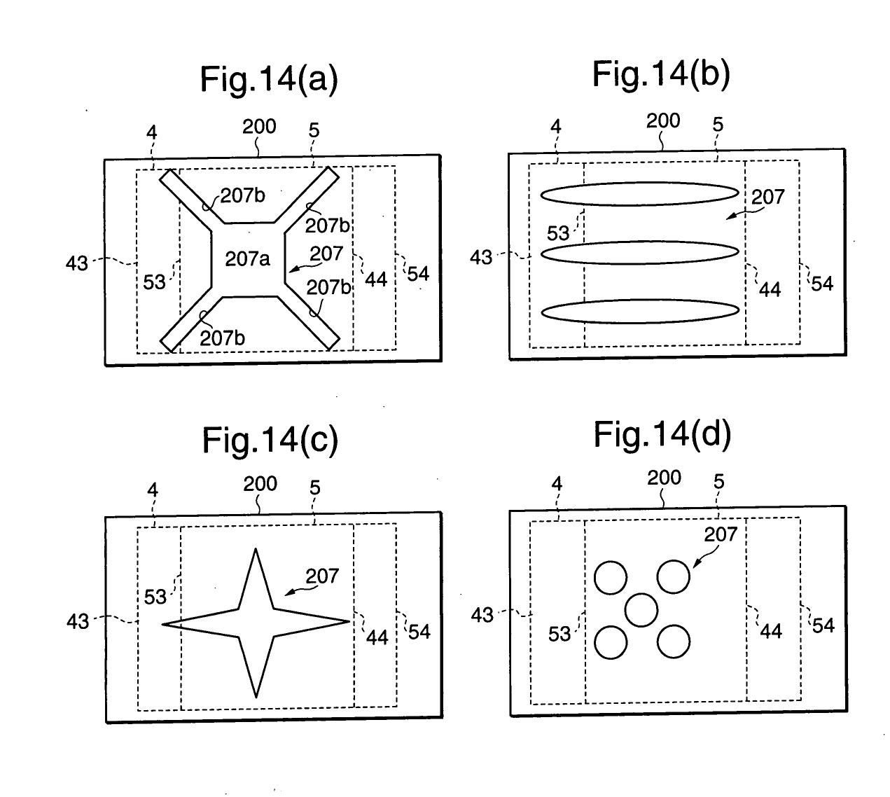

FIG. 13 shows calculated values of maximum stresses that act on the semiconductor chip 4 where no through section is provided in the die pad section 200 and the through section is defined in the portion in the die pad section 200, where only the semiconductor chip 4 is disposed. When the through section was provided, the maximum stress at a portion above the through section of the semiconductor chip 4 was calculated. When no through section is provided, stress applied to the semiconductor chip 4 at the same position as the position where the through section was provided, was calculated. As is understood from the same drawing, when the through section is provided, the stress concentrates on the portion above the through section of the semiconductor chip 4 and becomes large than that at the time that no through section is provided. At this time, there is a fear that since the strength of one semiconductor chip 4 is provided above the through section, the semiconductor chip 4 is deteriorated at the portion above the through section. Thus, in the present embodiment, major parts of through sections 207 are respectively defined in portions where semiconductor chips 4 and 5 overlap in die pad sections 200 as shown in FIG. 14.

The through section 207 shown in the same figure (a) has a substantially rectangular central portion 207a and radial portions 207b that extend outwardly from the central portion 207a along diagonal lines. Parts on the leading end sides, of the radial portions 207b are formed at a portion where only the semiconductor chip 4 is disposed, whereas most of the through section 207 is formed at a portion where the semiconductor chips 4 and 5 overlap each other.

The through section 207 shown in the same figure (b) has a plurality of bar-shaped portions parallel to one another. Parts of the respective bar-shaped portions are respectively formed at a portion where only the semiconductor chip 4 is disposed, whereas most of the through section 207 is formed at a portion where the semiconductor chips 4 and 5 overlap each other.

The through section 207 shown in the same figure (c) has a cross-shaped portion whose leading ends are at sharp angles. Part of the cross-shaped portion is formed at a portion where only the semiconductor chip 4 is disposed, whereas most of the through portion 207 is formed at a portion where the semiconductor chips 4 and 5 overlap each other.

The through section 207 shown in the same figure (d) has a plurality of substantially circular portions. The respective substantially circular portions are formed at a portion where the semiconductor chips 4 and 5 overlap each other.

Although the four types of through sections 207 have been shown in the present embodiment, the shapes of the through sections 207 are not limited to these. Most of the through section 207 may be formed at the portion where the semiconductor chips 4 and 5 overlap each other. Incidentally, the semiconductor device 1 according to the present embodiment is manufactured by preparing a lead frame 2 having such through sections 207 as shown in FIG. 14 and then using a manufacturing method similar to the first embodiment.

If most of the through section 27 is formed at the portion where the semiconductor chips 4 and 5 overlap each other, as in the present embodiment, then the strength of the semiconductor chip 4 is high since the semiconductor chip 5 is disposed so as to overlap with the semiconductor chip 4 at this portion even if the stress concentrates on the semiconductor chip 4 at the portion above the through section 207 upon the process of assembling the semiconductor device 1 (upon dismounting the semiconductor device 1 subsequent to the resin encapsulation from the die), thus making it possible to suppress deterioration of the semiconductor chip 4 at the portion above the through portion 207.

Thus, according to the semiconductor device 1 according to the present embodiment, it is possible to suppress deterioration of the semiconductor chip 5 at the edge portion E upon the assembling process. Further, since most of the through section 207 is formed at the portion where the semiconductor chips 4 and 5 are disposed so as to overlap each other in the die pad section 200, it is possible to suppress deterioration of the semiconductor chip 4 at the portion above the through section 207 and cause the through section 207 to reduce stress produced between the semiconductor chip 4 and the die pad section 200.

Incidentally, although the through section 207 is formed at the portion where the semiconductor chips 4 and 5 overlap each other in the above, the through section 207 may be formed at a portion in which no semiconductor chip 4 is disposed, as shown in FIG. 12(b). Since the semiconductor chip 4 is not placed at a portion above the through section 207 in this case, there is no fear that the semiconductor chip 4 is deteriorated at the portion above the through section 207.

### Third Embodiment

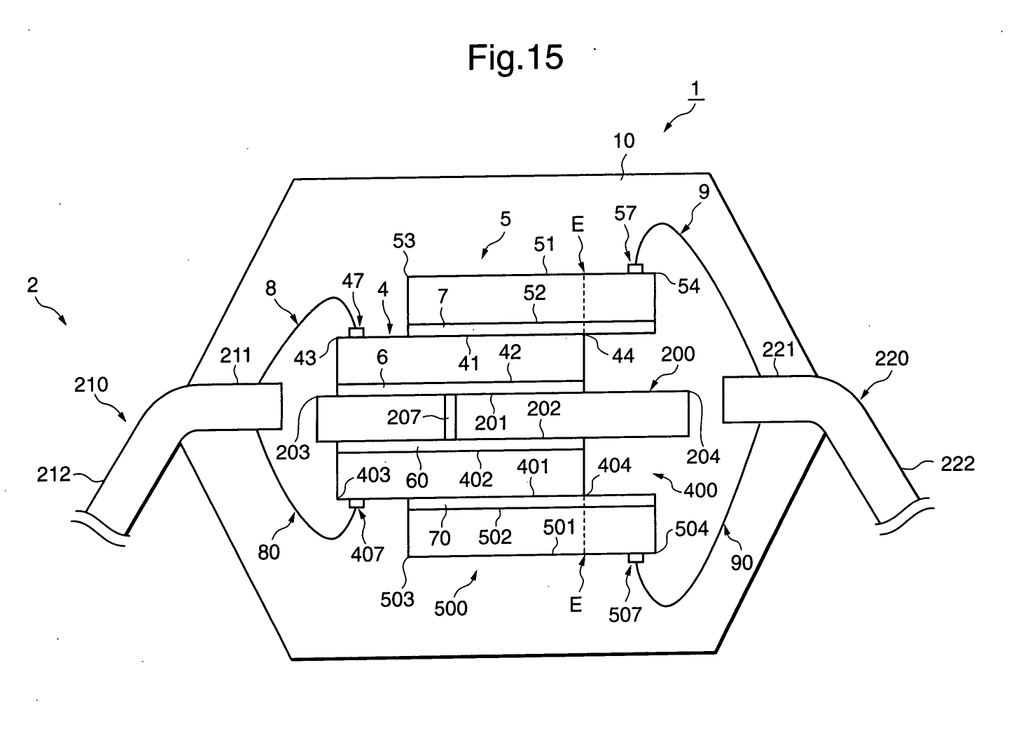

FIG. 15 is a cross-sectional view of a semiconductor device 1 according to a third embodiment of the present invention.

Although the semiconductor chips 4 and 5 are laminated on the surface 201 of the die pad section 200 in the above, semiconductor chips 400 and 500 may be laminated even on a surface 202 of a die pad section 200 as shown in FIG. 15. Since the semiconductor chips 400 and 500 are similar in structure to the semiconductor chips 4 and 5, their detailed description will be omitted.

The semiconductor chip 400 is fixed to the surface 202 of the die pad section 200 through an adhesive 60 interposed therebetween over the entire area of a surface 402 in such a manner that a side 403 thereof is disposed on the side 203 side of the die pad section 200 in a state in which the surface 402 is placed face to face to the surface 202 of the die pad section 200. The semiconductor chip 500 is fixed to the semiconductor chip 400 through an adhesive 70 interposed therebetween in such a manner that in a state in which a surface 502 thereof is placed face to face to a surface 401 of the semiconductor chip 400, a surface 503 thereof is located inside from the side 403 of the semiconductor chip 400 and a side 504 thereof is located outside from a side 404 of the semiconductor chip 400 and inside from a side 204 of the die pad section 200. Here, the more the length of the side 204 of the die pad section 200, which protrudes outside from the side 404 of the semiconductor chip 400, increases, the more deterioration of the semiconductor chip 500 at an edge portion E can be suppressed due to the reason similar to the first embodiment. A through section 207 is formed at a portion where the semiconductor chips 4, 5, 400 and 500 overlap one another in the die pad section 200.

If the semiconductor chips 4, 5, 400 and 500 are respectively laminated on both surfaces (surfaces 201 and 202) of the die pad section 200 in this way, then the deterioration of the semiconductor chip 500 at the edge portion E can be suppressed due to the same reason as described as to the semiconductor chips 4 and 5 since the side 504 of the semiconductor chip 500 is disposed so as to be located inside from the side 204 of the die pad section 200 even with respect to the surface 202. Since the semiconductor chips 4, 5, 400 and 500 are laminated over both surfaces of the die pad section 200, the number of semiconductor chips accommodated in the semiconductor device 1 can be doubled. Since the semiconductor chip 4 overlaps with the semiconductor chip 5 at a portion above the through section 207, the semiconductor chip 4 is high in strength so that deterioration thereof due to stress concentrated on the through section 207 is suppressed. Since the semiconductor chip 400 overlaps with the semiconductor chip 500 at a portion above the through section 207, the semiconductor chip 400 is high in strength so that deterioration thereof due to the stress concentrated on the through section 207 is suppressed.

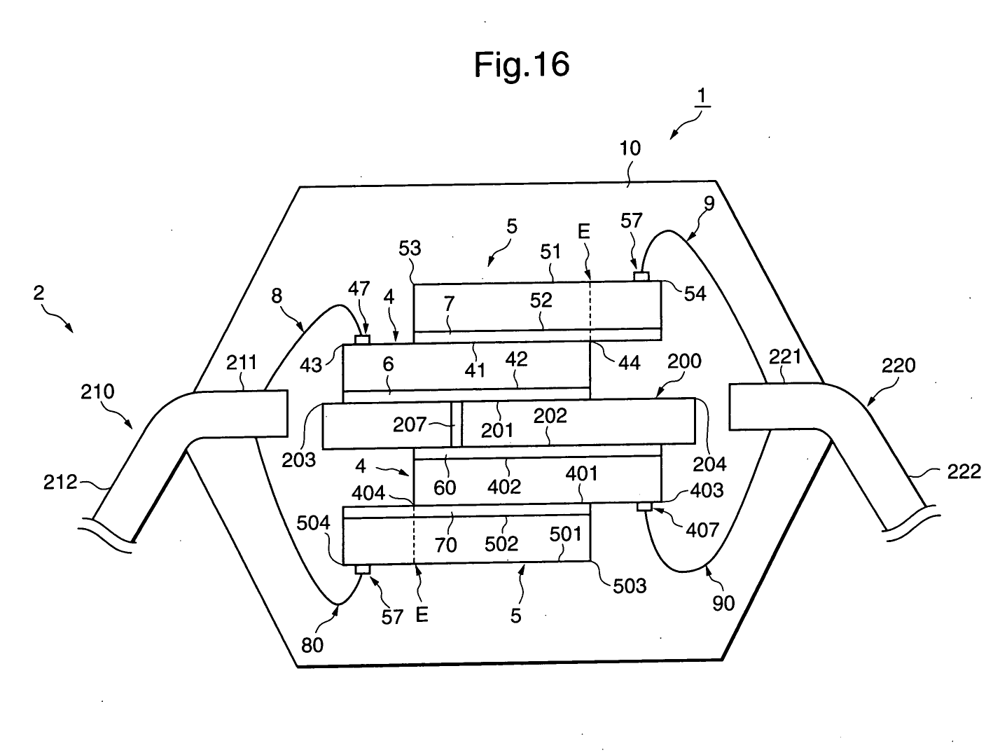

Incidentally, although the semiconductor chip 5 and the semiconductor chip 500 are shifted to a lead terminal section 220 in the present embodiment, the semiconductor chip 500 may be shifted to a lead terminal section 210. That is, as shown in FIG. 16, the semiconductor chip 400 may be fixed such that the side 403 is located on the side 204 side of the die pad section 200. Further, the semiconductor chip 500 may be fixed to the semiconductor chip 400 in such a manner that in a state in which the surface 502 of the semiconductor chip 500 is placed face to face to the surface 401 of the semiconductor chip 4, the side 503 of the semiconductor chip 500 is located inside from the side 403 of the semiconductor chip 400 and the side 504 of the semiconductor chip 500 is located outside from the side 404 of the semiconductor chip 400 and inside from the side 203 of the die pad section 200. Here, the more the length of the side 203 of the die pad section 200, which protrudes outside from the side 404 of the semiconductor chip 400, increases, the more deterioration of the semiconductor chip 500 at an edge portion E can be suppressed due to the reason similar to the first embodiment. A through section 207 is formed at a portion where the semiconductor chips 4, 5, 400 and 500 overlap one another in the die pad section 200.

The first through third embodiments respectively have described, by way of illustration, the case in which the semiconductor chips 4 and 5 are substantially identical in shape and size. However, if the portion of the semiconductor chip 4, which protrudes from the semiconductor chip 5, is placed and formed so as to overlap with the die pad section 200 even if the semiconductor chip 4 and the semiconductor chip 5 are different in shape and size, then deterioration of the semiconductor chip 4 at the edge portion E can be suppressed.

### Fourth Embodiment

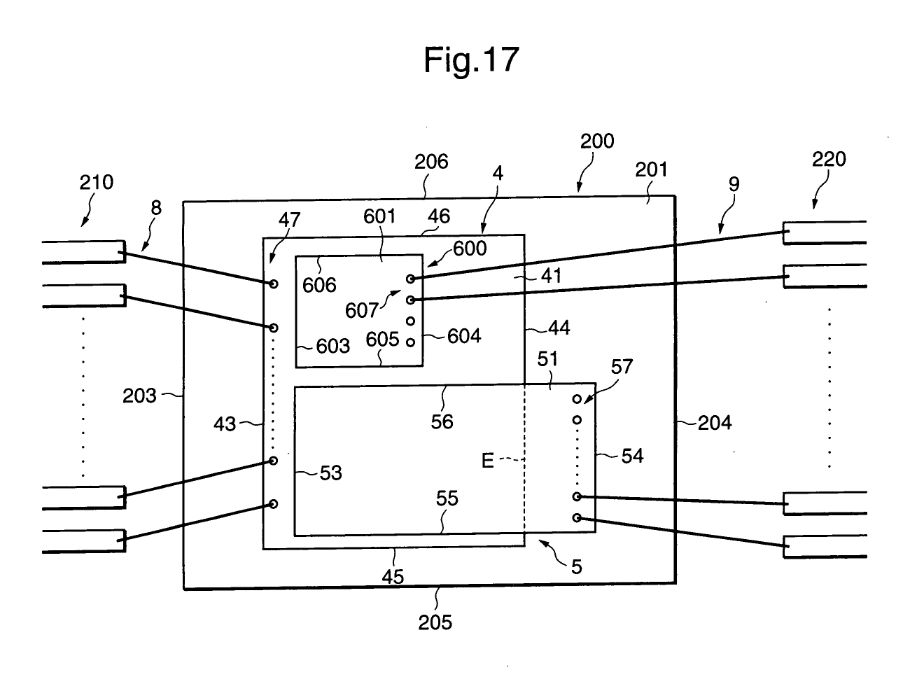

FIG. 17 is a plan view of a semiconductor device 1 according to a fourth embodiment of the present invention. Components similar to those employed in the first embodiment are respectively identified by the same reference numerals and the description thereof will therefore be omitted.

In the present embodiment, a semiconductor chip 600 is also fixed to a surface 41 of a semiconductor chip 4 in addition to a semiconductor chip 5. The semiconductor chip 600 has a surface 601 and an unillustrated surface opposite to the surface 601. The surface 601 has sides 603 and 604 opposite to each other, and sides 605 and 606 opposite respectively adjacent to the sides 603 and 604 and opposite to each other. The semiconductor chip 600 has an electrode section 607 on the side 604 side of the surface 601. The lengths of the sides 603 and 604 are respectively shorter than the lengths of sides 43 and 44 of the semiconductor chip 4. The lengths of the sides 605 and 606 are respectively shorter than the lengths of sides 45 and 46 of the semiconductor chip 4. The semiconductor chip 600 is fixed to the surface 41 of the semiconductor chip 4 so as to be contained in the semiconductor chip 4 as seen in the plane surface. The electrode section 607 of the semiconductor chip 600 is connected to a lead terminal section 220 by a wiring section 9.

Sides 53 and 54 of the semiconductor chip 5 are shorter than the sides 43 and 44 of the semiconductor chip 4. In a manner similar to the first embodiment, the semiconductor chip 5 is fixed to the semiconductor chip 4 in such a manner that the side 54 is located outside from the side 44 of the semiconductor chip 4 and inside from the side 204 of the die pad section 200.

Thus, since a portion of the semiconductor chip 5, which protrudes outside from the semiconductor chip 4, overlaps with the die pad section 200 even when the semiconductor chips 5 and 600 are fixed onto the semiconductor chip 4, deterioration of the semiconductor chip 5 at an edge portion E can be suppressed due to the reason similar to the first embodiment. Even in this case, the more the length of the side 204 of the die pad section 200, which protrudes outside from the side 44 of the semiconductor chip 4, increases, the more the effect of suppressing deterioration of the semiconductor chip 5 at the edge portion E increases.

Incidentally, if most of a through section 207 is formed at a portion where the semiconductor chip 5 or 600 overlaps with the semiconductor chip 4, then deterioration of the semiconductor chip 4 at a portion above the through section 207 can be suppressed due to the reason similar to the second embodiment even if stress concentrates on the semiconductor chip 4 at the portion above the through section 207.

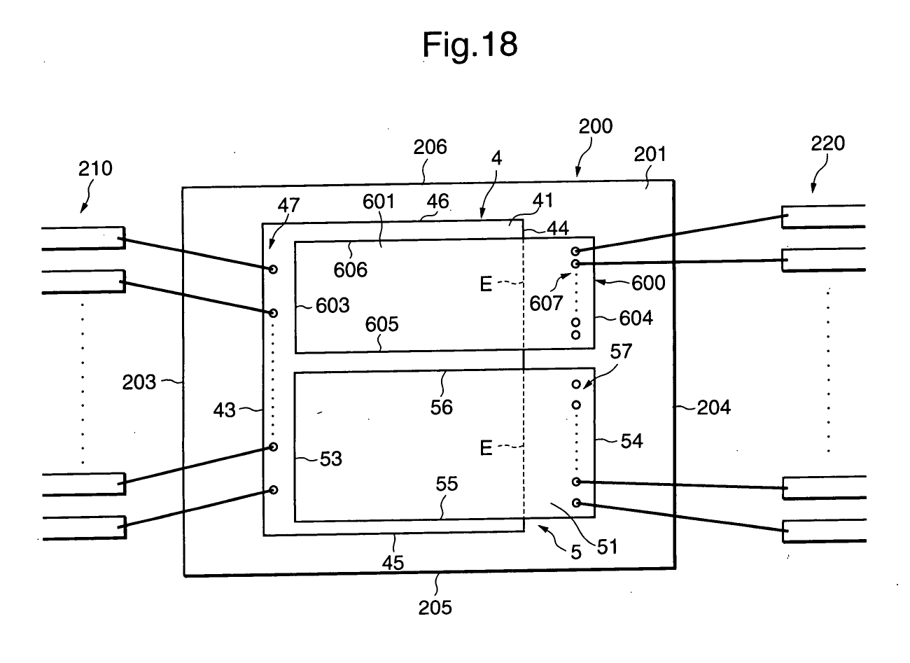

FIG. 18 is a plan view of the semiconductor device 1 where in FIG. 17, the semiconductor chip 600 also protrudes outside from the semiconductor chip 4. The semiconductor chip 600 is fixed to the surface 41 of the semiconductor chip 4 in such a manner that the side 604 thereof is located outside from the side 44 of the semiconductor chip 4 and inside from the side 204 of the die pad section 200.

Thus, when the semiconductor chips 5 and 600 are fixed onto the semiconductor chip 4, a portion of the semiconductor chip 5, which protrudes outside from the semiconductor chip 4, and a portion of the semiconductor chip 600, which protrudes outside from the semiconductor chip 4, are disposed so as to overlap with the die pad section 200. It is thus possible to restrain the maximum stress at edge portions E, of the semiconductor chips 5 and 600 and suppress deterioration of the semiconductor chips 5 and 600 at the edge portions E. Incidentally, the more the length of the side 204 of the die pad section 200, which protrudes outside from the side 44 of the semiconductor chip 4, increases, the more the effect of suppressing deterioration of the semiconductor chips 5 and 600 at the edge portions E increases as described above.

Even in this case, if most of a through section 207 is formed at a portion where the semiconductor chip 5 or 600 overlaps with the semiconductor chip 4, then deterioration of the semiconductor chip 4 at a portion above the through section 207 can be suppressed due to the reason similar to the second embodiment even if stress concentrates on the semiconductor chip 4 at the portion above the through section 207.

### Fifth Embodiment

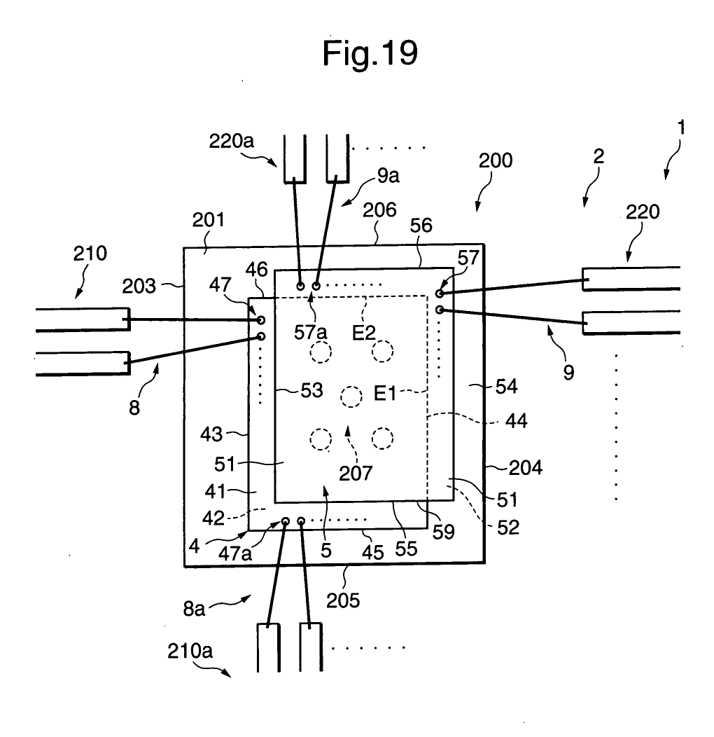

FIG. 19 is a plan view of a semiconductor device 1 according to a fifth embodiment of the present invention.

A lead frame 2 has a third lead terminal section 210a disposed with a predetermined interval with respect to a side 205 of a die pad section 200 and further includes a fourth lead terminal section 220a disposed with a predetermined interval with respect to a side 206 of the die pad section 200. A semiconductor chip 4 has an electrode section 47 that extends along a side 43 and an electrode section 47a that extends along a side 45. The electrode section 47 is connected to a lead terminal section 210 by a wiring section 8, and the electrode section 47a is connected to the lead terminal section 210a by a wiring section 8a. A semiconductor chip 5 has a wiring section 57 that extends along a side 54 and an electrode section 57a that extends along a side 56. The electrode section 57 is connected to a lead terminal section 220 by a wiring section 9, and the electrode section 57a is connected to a lead terminal section 220a by a wiring section 9a. The semiconductor chip 4 is fixed to a surface 201 of the die pad section 200 over the entire area of a surface 42 opposite to a surface 41. The semiconductor chip 5 is fixed to the semiconductor chip 4 through an adhesive interposed therebetween in such a manner that the side 54 of the semiconductor chip 5 is located outside from a side 44 of the semiconductor chip 4 and inside from a side 204 of the die pad section 200, and the side 56 of the semiconductor chip 5 is located outside from a side 46 of the semiconductor chip 4 and inside from the side 206 of the die pad section 200. Thus, even when the semiconductor chip 5 protrudes outside from the semiconductor chip 4 with respect to the adjacent two sides (sides 54 and 56), the die pad section 200 is disposed so as to overlap with a protruding portion of the semiconductor chip 5, so that the maximum stresses at edge portions E1 and E2, of the semiconductor chip 5 can be restrained and deterioration of the semiconductor chip 5 at the edge portions E1 and E2 can be suppressed. Incidentally, the more the length of the side 204 of the die pad section 200, which protrudes outside from the sides 44 and 46 of the semiconductor chip 4, increases, the more the effect of suppressing deterioration of the semiconductor chip 5 at the edge portions E1 and E2 increases.

If a through section 207 is defined in a portion (range surrounded by the side 53, the side 55, the edge portion E1 and the edge portion E2) of the die pad section 200 in which the semiconductors 4 and 5 overlap each other, then deterioration of the semiconductor chip 4 at a portion above the through section 207 can be suppressed due to the reason similar to the second embodiment even if stress concentrates on the semiconductor chip 4 at the portion above the through section 207.

### Sixth Embodiment

Although the plurality of semiconductor chips are laminated in the form of two layers in the first through fifth embodiments, the present invention can be applied even to a case in which a plurality of semiconductor chips are laminated in the form of three layers or more.

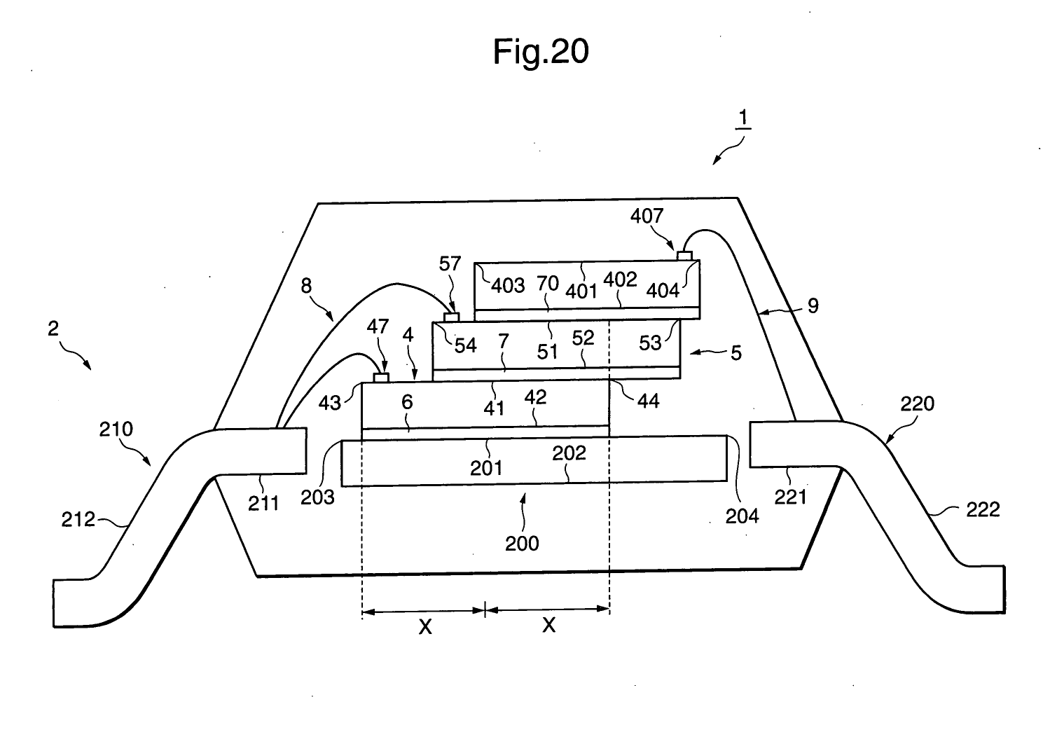

FIG. 20 is a cross-sectional view of a semiconductor device 1 according to a sixth embodiment of the present invention. The semiconductor device 1 according to the present embodiment is different from the semiconductor device 1 according to the first embodiment in that a semiconductor chip 400 is further laminated on a semiconductor chip 5.

The semiconductor chip 5 is fixed to a semiconductor chip 4 in such a manner that in a state in which a surface 52 is placed face to face to a surface 41 of the semiconductor chip 4, a side 54 is located inside a side 43 of the semiconductor chip 4 and a side 53 is located outside a side 44 of the semiconductor chip 4 and inside a side 204 of a die pad section 200.

The semiconductor chip 400 has surfaces 401 and 402 opposite to each other, and sides 403 and 404 opposite to each other. The semiconductor chip 400 has an electrode section 407 on the side 404 side of the surface 401. The electrode section 407 comprises a plurality of electrodes. The semiconductor chip 400 is fixed to the semiconductor chip 5 in such a way that in a state in which the surface 402 is placed face to face to a surface 51 of the semiconductor chip 5, the side 403 is located inside the side 54 and the side 404 is located outside from the side 53 of the semiconductor chip 5 and inside from the side 204 of the die pad section 200. A wiring section 9 electrically connects the electrode section 407 to a lead terminal section 220 on the near side as viewed from the electrode section 407.

In the present embodiment, the die pad section 200 is disposed in such a manner that it overlaps with a portion of the semiconductor chip 5, which protrudes from the semiconductor chip 4 and a portion of the semiconductor chip 400, which protrudes from the semiconductor chip 5. As a result, stress applied to each of a boundary portion (edge portion) of the semiconductor chip 5, which protrudes outside from the semiconductor chip 4, and a boundary portion (edge portion) of the semiconductor chip 400, which protrudes outside from the semiconductor chip 5, is reduced in a manner similar to the first embodiment, thus making it possible to suppress deterioration of the semiconductor chips 5 and 400 at the edge portions.

While the present invention has been described with reference to the illustrative embodiments, this description is not intended to be construed in a limiting sense. Various modifications of the illustrative embodiments, as well as other embodiments of the invention, will be apparent to those skilled in the art on reference to this description. It is therefore contemplated that the appended claims will cover any such modifications or embodiments as fall within the true scope of the invention.

1. A semiconductor device comprising:
a die pad section having a surface and a back surface;
a first semiconductor chip having a surface on which a first electrode section is formed, and a back surface fixed to the surface of the die pad section;
a second semiconductor chip having a surface on which a second electrode section is formed, and a back surface fixed to the surface of the first semiconductor chip;
lead terminal sections respectively electrically connected to the first and second electrode sections; and
a resin encapsulating body that seals the die pad section, and the first and second semiconductor chips,
wherein an edge portion of the second semiconductor chip protrudes from an edge portion of the first semiconductor chip, and an edge portion of the die pad section protrudes from the edge portion of the first semiconductor chip.

2. A semiconductor device according to claim 1, wherein the edge portion of the die pad section further protrudes from the edge portion of the second semiconductor chip.

3. A semiconductor device according to claim 2, wherein the surface of the first semiconductor chip has first and second sides opposite to each other,
the surface of the second semiconductor chip has third and fourth sides opposite to each other,
the surface of the die pad section has fifth and sixth sides opposite to each other,
the fourth side of the second semiconductor chip protrudes from the second side of the first semiconductor chip, and
the sixth of the die pad section protrudes from the fourth side of the second semiconductor chip.

4. A semiconductor device according to claim 3, wherein the first and second semiconductor chips are substantially identical in shape and size.

5. A semiconductor device according to claim 4, wherein when the length between the first and second sides of the second semiconductor chip is defined as a chip length, the length of the sixth side of the die pad section, which protrudes from the fourth side of the second semiconductor chip, is less than or equal to one-fourth the chip length.

6. A semiconductor device according to claim 5, wherein the length of the fourth side of the second semiconductor chip, which protrudes from the second side of the first semiconductor chip, is over 0.1 times half of the chip length and under 0.3 times half of the chip length.

7. A semiconductor device according to claim 6, wherein the thickness of each of the first and second semiconductor chips is over 0.02 times half of the chip length and under 0.06 times half of the chip length.

8. A semiconductor device according to claim 1, wherein the die pad section further includes a through section principally defined in a portion where the first and second semiconductor chips overlap each other.

9. A semiconductor device according to claim 8, wherein the through section is formed only at the portion where the first and second semiconductor chips overlap each other.

10. A semiconductor device according to claim 9, wherein the through section includes either of radial portions, bar-shaped portions, a cross-shaped portion or substantially circular portions.

11. A semiconductor device according to claim 1, wherein the die pad section and the first and second semiconductor chips are substantially rectangular, adjacent two sides of the second semiconductor chip protrude from adjacent two sides of the first semiconductor chip respectively, and adjacent two sides of the die pad section protrude from the two sides of the first semiconductor chip respectively.

12. A semiconductor device according to claim 1, further comprising:
a third semiconductor chip having a surface on which a third electrode section electrically connected to the lead terminal section is formed, and a back surface fixed to the back surface of the die pad section, and
a fourth semiconductor chip having a surface on which a fourth electrode section electrically connected to the corresponding lead terminal section, and a back surface fixed to the surface of the third semiconductor chip,
wherein an edge portion of the fourth semiconductor chip protrudes from an edge portion of the third semiconductor chip and the edge portion of the die pas section protrudes from the edge portion of the third semiconductor chip.

13. A semiconductor device according to claim 1, further comprising a fifth semiconductor chip fixed to the first semiconductor chip together with the second semiconductor chip.

14. A semiconductor device according to claim 13, wherein an edge portion of the fifth semiconductor chip protrudes from the edge portion of the first semiconductor chip.

15. A semiconductor device comprising:
a first semiconductor chip having a first surface and a second surface opposite to the first surface and on which a first electrode section is formed, said second surface having a first side and a second side opposite to the first side;
a second semiconductor chip having a third surface fixed onto the second surface, and a fourth surface opposite to the third surface and on which a second electrode section is formed, said fourth surface having a third side and a fourth side opposite to the third side;
a die pad section to which the first semiconductor chip is fixed, said die pad section having a first region to which the first surface is fixed, and a second region that protrudes from the second side;
lead terminal sections respectively electrically connected to the first and second electrode sections; and
a resin encapsulating body that seals the die pad section, and the first and second semiconductor chips,
wherein the fourth side of the second semiconductor chip protrudes from the second side of the first semiconductor chip.

16. A semiconductor device according to claim 15, wherein the die pad section further has a third region that protrudes from the first side, and the amount of protrusion of the third region is larger than the amount of protrusion of the second region.

17. A semiconductor device according to claim 15, wherein the second region further protrudes from the fourth side of the second semiconductor chip.

18. A semiconductor device according to claim 17, wherein the first and second semiconductor chips are substantially identical in shape and size.

19. A semiconductor device according to claim 18, wherein when the length between first and second sides of the second semiconductor chip is defined as a chip length, the length of the second region, which protrudes from the fourth side of the second semiconductor chip, is less than or equal to one-fourth the chip length.

20. A semiconductor device according to claim 19, wherein the length of the fourth side of the second semiconductor chip, which protrudes from the second side of the first semiconductor chip, is over 0.1 times half of the chip length and under 0.3 times half of the chip length.

21. A semiconductor device according to claim 20, wherein the thickness of each of the first and second semiconductor chips is over 0.02 times half of the chip length and under 0.06 times half of the chip length.

22. A semiconductor device according to claim 15, wherein the die pad section further includes a through section principally defined in a portion where the first and second semiconductor chips overlap each other.

23. A semiconductor device according to claim 22, wherein the through section is formed only at the portion where the first and second semiconductor chips overlap each other.

24. A semiconductor device according to claim 23, wherein the through section includes either of radial portions, bar-shaped portions, a cross-shaped portion or substantially circular portions.

25. A semiconductor device according to claim 15, wherein the second surface of the first semiconductor chip further has a fifth side adjacent to the second side,
the fourth surface of the second semiconductor chip further has a sixth side adjacent to the fourth side,
the die pad section further has a fourth region that protrudes from the fifth side, and
the sixth side of the second semiconductor chip protrudes from the fifth side of the first semiconductor chip.

26. A semiconductor device according to claim 15, further comprising:
a third semiconductor chip having a fifth surface and a sixth surface opposite to the fifth surface and on which a third electrode section electrically connected to the corresponding lead terminal section is formed, said sixth surface having a seventh side, and
a fourth semiconductor chip having a seventh surface fixed onto the sixth surface, and an eighth surface opposite to the seventh surface and on which a fourth electrode section electrically connected to the corresponding lead terminal section is formed, said eighth surface having an eighth side,
wherein the die pad section further includes, on a surface opposite to a surface formed with the first and second regions, a fifth region to which the fifth surface is fixed, and a sixth region that protrudes from the seventh side, and
the eighth side of the fourth semiconductor chip protrudes from the seventh side of the third semiconductor chip.

27. A semiconductor device according to claim 15, further comprising a fifth semiconductor chip fixed to the first semiconductor chip together with the second semiconductor chip.

28. A semiconductor device according to claim 27, wherein an edge portion of the fifth semiconductor chip protrudes from the second side of the first semiconductor chip.

29. A method of manufacturing a semiconductor device provided with a first semiconductor chip having a surface on which a first electrode section is formed, and a back surface opposite to the surface, a second semiconductor chip having a surface on which a second electrode section is formed, and a back surface opposite to the surface, a die pad section, lead terminal sections and a resin encapsulating body, said method comprising the following steps of:
fixing the back surface of the first semiconductor chip to the die pad section such that an edge portion of the die pad section protrudes from an edge portion of the first semiconductor chip;
fixing the back surface of the second semiconductor chip to the surface of the first semiconductor chip such that an edge portion of the second semiconductor chip protrudes from the edge portion of the first semiconductor chip;
electrically connecting the first and second electrode sections to the lead terminal sections; and
sealing the first and second semiconductor chips and the die pad section with the resin encapsulating body.

30. A method of manufacturing a semiconductor device provided with a first semiconductor chip having a first surface and a.second surface opposite to the first surface and on which a first electrode section is formed, said second surface having a first side and a second side opposite to the first side, a second semiconductor chip having a third surface and a fourth surface opposite to the third surface and on which a second electrode section is formed, said fourth surface having a third side and a fourth side opposite to the third side, a die pad section having a first region and a second region, lead terminal sections, and a resin encapsulating body, said method comprising the following steps of:
fixing the first surface of the first semiconductor chip to the first region of the die pad section such that the second region of the die pad section protrudes from the second side of the first semiconductor chip;
fixing the third surface of the second semiconductor chip to the second surface of the first semiconductor chip such that the fourth side of the second semiconductor chip protrudes from the second side of the first semiconductor chip;
electrically connecting the first and second electrode sections to the lead terminal sections; and
sealing the first and second semiconductor chips and the die pad section with the resin encapsulating body.
